(19) United States
(12) Patent Application Publication
(10) Pub. No.: US 2008/0308411 A1
(43) Pub. Date: Dec. 18, 2008

(54) METHOD AND PROCESS FOR DEPOSITION OF TEXTURED ZINC OXIDE THIN FILMS

(75) Inventors: Sheyu Guo, Wallingford, PA (US); Alan E. Delahoy, Rocky Hill, NJ (US)

Correspondence Address: BROOKS KUSHMAN P.C., 1000 TOWN CENTER, TWENTY-SECOND FLOOR, SOUTHFIELD, MI, 48075, US

(73) Assignee: ENERGY PHOTOVOLTAICS, INC., Lawrenceville, NJ (US)

(21) Appl. No.: 12/127,470

(22) Filed: May 27, 2008

Related U.S. Application Data
(60) Provisional application No. 60/940,297, filed on May 25, 2007.

(51) Int. Cl. C23C 14/00

(52) U.S. Cl. 204/192.15

(57) ABSTRACT

A method for sputtering a textured zinc oxide coating onto a substrate by reactive-environment hollow cathode sputtering comprises providing a sputter reactor that has a cathode channel and a flow exit end. The cathode channel allows a gas stream to flow therein. This cathode channel is at least partially defined by a channel-defining surface that includes at least one zinc-containing target. A gas is flowed through the channel, such that the gas emerges from the flow exit. A plasma is then generated such that material is sputtered off the channel-defining surface to form a gaseous mixture containing zinc atoms that is transported to the substrate. A reactive gas is then introduced into the sputter reactor so that the reactive gas reacts with the zinc-containing gaseous mixture to form the textured zinc oxide coating.

### CROSS-REFERENCE TO RELATED APPLICATIONS

This application claims the benefit of U.S. provisional application Ser. No. 60/940,297 filed May 25, 2007, the entire disclosure of which is hereby incorporated by reference.

### BACKGROUND OF THE INVENTION

1. Field of the Invention

The present invention is related to the preparation of zinc oxide films having sufficient surface texturing to improve a solar cell's efficiency.

2. Background Art

Solar cells and modules are readily manufactured by plasma enhanced chemical vapor deposition (“PECVD”) of hydrogenated amorphous silicon (a-Si:H) onto a substrate. The typical substrate consists of glass coated with a transparent conducting coating (“TCO”) i.e. onto a PVTCO. The standard PVTCO consists of a pyrolytic coating of SnO₂:F on glass. This type of PVTCO is commercially available from several glass companies. Photovoltaic solar cells are also prepared stainless steel substrates. In this case, a TCO must be provided as a transparent and conductive top electrode.

The standard approaches to the formation of textured ZnO are direct deposition by LPCVD (provide details), or magnetron sputtering of ZnO followed by 0.5% HCl etching. However, the former material is unstable and the latter involves an undesirable wet chemical step involving acid. Direct deposition by LPCVD method is thermally activated, therefore requiring extreme temperature uniformity is required.

The successful development of well-textured ZnO promises to triple the QE at 800 nm from 0.2 to 0.6 (or to increase J_{sc} from 15.6 mA/cm² to 26.8 mA/cm²) for nc-Si cells. Light trapping is employed by texturing the front window layer TCO. Traditionally, amorphous silicon (a-Si:H) thin film solar cells are fabricated on textured fluorine-doped tin oxide (SnO₂:F). SnO₂ is susceptible to reduction when exposed to atomic hydrogen during a-Si deposition, which can make the tin oxide TCO turn dark. A better quality of SnO2 (Asahi type-U) is available but it is not economical for the photovoltaics production industry.

Accordingly, there is a need for a method for direct deposition of textured, transparent, conductive ZnO films. The method should be capable of large area, uniform deposition and should be of low cost.

### SUMMARY OF THE INVENTION

The present invention solves one or more problems of the prior art, by providing in at least one embodiment a method for sputtering a textured zinc oxide coating onto a substrate by reactive-environment hollow cathode sputtering. The method of this embodiment comprises providing a sputter reactor that has a cathode channel and a flow exit end. The cathode channel allows a gas stream to flow therein and exit from the flow exit end. This cathode channel is at least partially defined by a channel defining surface that includes at least one zinc containing target and an optional dopant target. The dopant target when present is positioned to provide dopant atoms to the gas stream when the gas stream is flowed through the cathode channel. A gas is flowed through the channel, such that the gas emerges from the flow exit. A plasma is then generated such that material is sputtered off the channel-defining surface and the dopant target to form a gaseous mixture containing zinc atoms and dopant atoms (if present) that are transported to the substrate. A reactive oxygen-containing gas is then introduced into the sputter reactor so that the reactive gas reacts with the zinc supplied by the zinc-containing gaseous mixture to form the textured zinc oxide coating. Advantageously, the texture zinc oxide coating scatters at least 1% of visible light incident thereon. It should be appreciated that dopants may also be introduced via reactant gases or by a secondary sputtering target. The present embodiment allows for the direct deposition of textured ZnO without the need for post-deposition etching. The utilization of reactive-environment hollow cathode sputtering allows the use of linear sources that can be scaled for large coating widths. Moreover, the methods of the present embodiment are reliable, use low cost metal targets (no need for expensive ceramic targets), and do not require high vacuum pumps. Surprisingly, the method of the present embodiment is capable of achieving low film resistivities, typically about 7×10⁻⁴ ohm cm, and as low as about 2.9×10⁻⁴ ohm cm.

### BRIEF DESCRIPTION OF THE DRAWINGS

FIG. 1A is a schematic illustration showing the incorporation of a zinc oxide layer in a photovoltaic device;

FIG. 1B is another schematic illustration showing the incorporation of a zinc oxide layer in a photovoltaic device;

FIG. 2 is a schematic illustration of an exemplary RE-HCS sputtering apparatus is provided;

FIG. 3 is an SEM micrograph of textured ZnO:Al film deposited by RE-HCS;

FIG. 4 is an SEM micrograph of textured ZnO:Al film deposited by RE-HCS under the conditions described;

FIG. 5 is an SEM of zinc oxide deposited from traditional RF sputtering;

FIG. 6 provides an SEM of a 1 micron thick ZnO film deposited on a substrate at a temperature of 230° C. using water as the oxygen source;

FIG. 7 provides an SEM of a 1 micron thick ZnO film deposited with a RF bias of −80 V on a substrate at a temperature of 230° C. using water as the oxygen source;

FIG. 8 provides an SEM of a 1 micron thick ZnO film deposited on a substrate at a temperature of 230° C. using molecular oxygen as the oxygen source. The bias used for this deposition was −80 V.

FIG. 9 provides an SEM of a 1 micron thick ZnO film deposited on a substrate at a temperature of 160° C. using molecular oxygen and water as the oxygen source;

FIG. 10 provides an SEM of a 0.58 micron thick ZnO film deposited on a substrate at a temperature of 335° C. using molecular oxygen as the oxygen source.

FIG. 11 provides an SEM of a 0.36 micron thick ZnO film deposited on a substrate at a temperature of 120° C. using molecular oxygen as the oxygen source. The RF bias of for this deposition is −60 V.

FIG. 12 is thickness mapping (in nm) of a typical ZnO:Al film (deposited on 12″×15″ glass from run#309);

FIG. 13 is an XRD spectra of the ZnO:Al film deposited at two different temperatures;

FIG. 14 is SEM micrograph of ZnO:Al films a) as deposited textured film b) plasma treated;

FIG. 15 provides the total and diffuse optical transmission of Commercial SnO₂:F and RE-HCS ZnO:Al;

FIG. 16 provides J-V curves of a single junction a-Si:H cell deposited on commercial SnO₂:F and on directly textured ZnO:Al deposited by RE-HCS;

FIG. 17A provides an atomic force micrographs for textured, doped ZnO films deposited by the RE-HCS process;

FIG. 17B provides an atomic force micrographs for a commercially available SnO2:F film;

FIG. 18A provides an SEM of a CIGS device coated by non-textured ZnO:Al film deposited by RF sputtering;

FIG. 18B provides a CIGS device coated by a textured ZnO:Al film deposited by RE-HCS; and

FIG. 19 provides a plot of the quantum efficiency versus wavelength for a CIGS device coated by textured ZnO:Al and untextured ZnO:Al.

### DETAILED DESCRIPTION OF THE PREFERRED EMBODIMENT(S)

Reference will now be made in detail to presently preferred compositions, embodiments and methods of the present invention, which constitute the best modes of practicing the invention presently known to the inventors. The Figures are not necessarily to scale. However, it is to be understood that the disclosed embodiments are merely exemplary of the invention that may be embodied in various and alternative forms. Therefore, specific details disclosed herein are not to be interpreted as limiting, but merely as a representative basis for any aspect of the invention and/or as a representative basis for teaching one skilled in the art to variously employ the present invention.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. The description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

It must also be noted that, as used in the specification and the appended claims, the singular form “a”, “an”, and “the” comprise plural referents unless the context clearly indicates otherwise. For example, reference to a component in the singular is intended to comprise a plurality of components.

Throughout this application, where publications are referenced, the disclosures of these publications in their entireties are hereby incorporated by reference into this application in their entirety to more fully describe the state of the art to which this invention pertains.

In an embodiment of the present invention, textured zinc oxide films that increase the efficiency of photovoltaic devices are provided. The present embodiment advantageously increases the amount of light trapping in a photovoltaic thin film stack. Light trapping allows for the effective absorption of incident sunlight on such a photovoltaic device thereby increasing the generation of the electron-hole pairs.

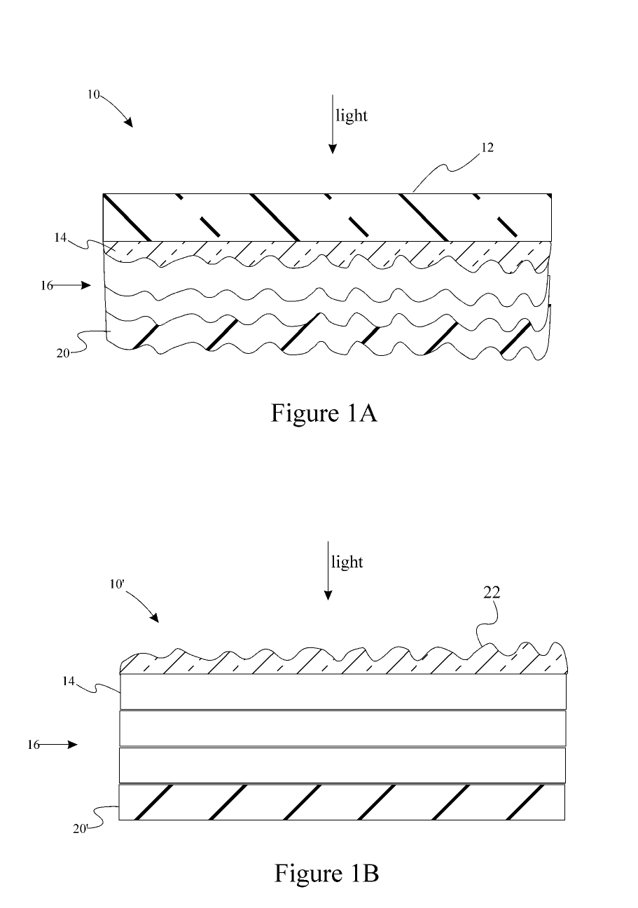

With reference to FIG. 1A, a schematic illustration showing the incorporation of a zinc oxide layer in a photovoltaic device is provided. Photovoltaic device 10 includes transparent substrate 12 (e.g. glass), which is over-coated by zinc oxide layer 14. Photovoltaic active layers 16 are in turn disposed over zinc oxide layer 14. Characteristically, zinc oxide layer 14 includes texturing that induces the light trapping effect for light incident into the photovoltaic active layers. Reflective rear electrode 20 allow light to be reflected back into photovoltaic device 10. Light is incident into device 10 from the side having transparent substrate 12.

Still referring to FIG. 1A, zinc oxide layer 14 possesses a surface roughness on an appropriate length scale to scatter light. Zinc oxide layer 14 scatters and diffuses incident light so that it enters the cell over a range of angles. Furthermore, when photovoltaic layers 16 (e.g. a-Si or more generally thin Si) is deposited on the textured zinc oxide, the texture is approximately replicated at the back surface i.e., reflective rear electrode 20. In a refinement, the texturing of zinc oxide layer 14 is transferred to reflective rear electrode 20. This helps scatter light that is reflected from the rear electrode and enhances total internal reflection at the front interface between Zinc oxide layer 14 and the photovoltaic active layers thus contributing to light trapping. When the light reaches the front of the cell and impinges at an angle greater than the critical angle it can be totally internally reflected into the cell for a third pass. In a refinement of the present embodiment, the light may make 5 or even 10 passes before being absorbed.

With reference to FIG. 1B, a schematic illustration showing the incorporation of a zinc oxide layer in another photovoltaic device is provided. In this variation, photovoltaic device 10′ includes photovoltaic active layers 16 which are disposed over substrate 20′. Substrate 20′ is typically a metal such as stainless steel. Zinc oxide layer 14 is disposed over photovoltaic active layers 16. Surface 22 of zinc oxide layer 14 includes a sufficient amount of surface texturing to induce light trapping in device 10′ which light is incident on this surface.

In accordance with the present embodiment, textured, conducting ZnO thin films are formed using the reactive-environment hollow cathode sputtering method (“RE-HCS”) under particular ranges of deposition conditions. The RE-HCS is described in U.S. Pat. No. 7,235,160 and U.S. Patent Publication Nos. 20050029088 and 20060118406. The entire disclosure of these applications are hereby incorporated by reference. Unlike typical sputtering processes such as magnetron sputtering, it has been surprisingly found that the RE-HCS sputtering process of the present embodiment under suitable conditions forms zinc oxide films that are sufficiently textured to increase the efficiency of photovoltaic devices and in particular solar cells.

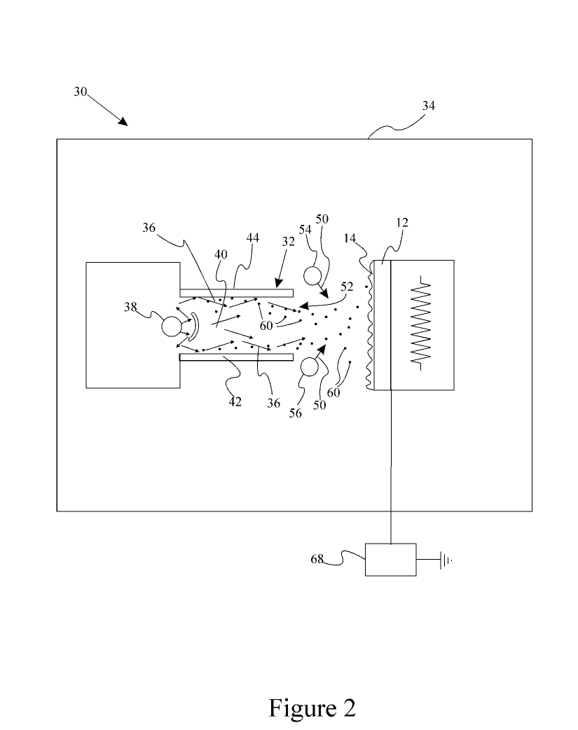

With reference to FIG. 2, a schematic illustration of an exemplary RE-HCS sputtering apparatus is provided. RE-HCS sputtering system 30 includes hollow cathode 32 and reaction chamber 34. Working gas 36 (e.g. Ar) is introduced via nozzle 38 and flowed through cavity 40 of hollow cathode 32 whose internal surfaces are at least partially defined by a channel-defining surface of target materials 42, 44. At least one of target materials 42, 44 include zinc metal. Power for sputtering is applied to the hollow cathode 32 and to an anode. The power can be DC, pulsed DC, or mid-frequency bipolar. The target material is sputtered and target atoms or clusters 60 are carried to substrate 12 by the flow of the working gas. One or more reactive gases 50 (e.g. oxygen, water) can be supplied near flow exit end 52 of hollow cathode 32 to form zinc oxide film 14 on the substrate 12. These reactive gases are supplied to reaction chamber 34 via nozzles 54, 56.

In a variation of the present embodiment, turbulence in working gas 36 is advantageously used to directly increase the deposition rate and to inhibit back streaming of reactive gases 50 into cavity 40. During deposition of zinc oxide film 14 a reaction chamber pressure between 80 and 400 millitorr (“mT”) is established. Moreover, heater 62 is utilized to establish a substrate temperature greater than about 170° C. during film deposition. Advantageously, the method of the present embodiment produces a textured zinc oxide coating scattering at least 2% of visible light incident upon it.

As set forth above, target materials 42, 44 include zinc. Such zinc may be in the form of substantially pure zinc or zinc alloy metals. If pure Zn targets are used, a doping element such as B, Al, F, or Ga is added in order to achieve a sufficiently conducting and stable film. Boron can be added through use of a gaseous compound e.g. B₂H₆. Fluorine hydrocarbons maybe used for fluorine. Al and Ga can be added through alloying the target or by using an additional source or target. Substrate 12 is formed from virtually any substrate that is compatible with zinc oxide. Examples of such materials include, but are not limited to, soda lime glass, borosilicate glass, coated glass, and the like. Optionally, the substrate layer is coated with a blocking dielectric layer such as silicon oxide or aluminum oxide.

As set forth above, a reactive gas is introduced into chamber 34 to react with the sputtered zinc. Examples of such reactive gases include, but are not limited to, oxygen, oxygen and water vapor mixture, or water vapor alone. The introduction of water vapor flow can be controlled by using a carrying gas such as Ar. The morphology of the deposited films can be manipulated via the amount of water vapor supplied as demonstrated in the examples below. In a refinement, the use of water vapor promotes texturing of the zinc oxide films of the present embodiment. Typically, water is added at a rate from about 10 to about 200 sccm.

Substrate 12 may be biased or unbiased. In a refinement, substrate bias is applied by RF supply 68. A negative bias appears on the substrate and the voltage can be controlled by adjusting RF power. The morphology shows differences that are at least somewhat dependent on surface texturing. In a refinement, the surface texturing of the zinc oxide films is higher with no bias.

The zinc oxide films are observed to become rougher at higher temperatures (i.e., temperatures above 170° C.). In a refinement of the present variation, the substrate temperature onto which the zinc oxide films are deposited are at a temperature from about 170° C. to about 400° C. In another refinement of this variation, the substrate temperature onto which the zinc oxide films are deposited are at a temperature from about 250° C. to about 350° C. In general, the depositions of the present embodiment are performed at reduced pressure, but at pressure that is substantially higher than the prior art magnetron sputtering processes. Typically, the pressure is from about 80 mtorr to about 500 mtorr.

The zinc oxide films of the present invention are characterized having an observable surface texturing or roughness. In one variation, this texturing is characterized by scattering from about 1% to about 75% of incident light having a wavelength in the visible and near-IR portion of the light spectrum (these are the values for a zinc oxide film on substrate). In another variation, this texturing is characterized by scattering from about 2% to about 50% of incident light having a wavelength in the visible and near-IR portion of the light spectrum. In another variation, this texturing is characterized by scattering from about 20% to about 60% of incident light having a wavelength in the visible and near-IR portion of the light spectrum. This range is useful or a-Si/nanocrsytalline silicon hybrid modules. In another variation, this texturing is characterized by scattering from about 10% to about 20% of incident light having a wavelength in the visible and near-IR portion of the light spectrum. This latter range is particularly useful for a-Si applications. The texturing is also characterized by the observation of surface features having a size dimension greater than about 0.5 microns as observed by a scanning electron micrograph (“SEM”) of a zinc oxide surface. In a refinement, the surface features are defined by particles, grains, or protrusions from the surface of zinc oxide. In one variation, at least 10% of the surface features have a size dimension greater than about 0.5 microns as observed by a scanning electron micrograph (“SEM”) of a zinc oxide surface. In another variation, at least 20% of the surface features have a size dimension greater than about 0.5 microns as observed by a scanning electron micrograph (“SEM”) of a zinc oxide surface. In still another variation, at least 30% of the surface features have a size dimension greater than about 0.5 microns as observed by a scanning electron micrograph (“SEM”) of a zinc oxide surface.

In a variation of the present invention, the zinc oxide films are sufficiently doped so that the resistivity is less than 5×10⁻³ ohm-cm. In other variation, the zinc oxide films are sufficiently doped so that the resistivity is less than 1×10⁻³ ohm-cm. Typically, the resistivity is greater than 1×10⁻⁴ ohm-cm.

In another variation of the present embodiment, the zinc oxide films are observed to become rougher as the thickness of the films is increased. In refinement, the thickness of the deposited zinc oxide films is from 0.5 microns to about 3.0 microns. In another refinement, the thickness of the deposited zinc oxide films is from 1.0 micron to about 3.0 microns. In still another refinement, the thickness of the deposited zinc oxide films is from 1.0 micron to about 2.5 microns.

In still another variation of the present embodiment, photovoltaic active layers are formed from a-Si. Such layers are prepared either as a single junction (p-i-n) type, or a tandem junction (p-i-n/p-i-n) type. As in all thin film solar cells, light trapping allows weakly absorbed light that penetrates to the rear of the cell to reflected by a reflective rear electrode back through the cell so that it has a second chance of being absorbed. The band gap of a-Si is about 1.75 eV. Ge may also be alloyed into the a-Si to form a-Si,Ge with a somewhat lower band gap in the range 1.45-1.65 eV. Tandem or triple junction cells can be made using a-Si and a-Si,Ge. The stabilized efficiencies of large area modules made using these materials tend to fall in the range 5%-8%. In another refinement nc-Si:H is used as the photovoltaic active material. This material contains very small crystallites approximately 10 nm in diameter. Its effective band gap is 1.1 eV and it possesses much weaker optical absorption than does a-Si. Unlike a-Si, nc-Si can absorb light in the near IR portion of the spectrum i.e. up to about 1100 nm. In still another refinement, the textured zinc oxide of the present embodiment is incorporated into solar cells consisting of a tandem junction of a-Si and nc-Si (hybrid tandem). Because of the weak optical absorption of nc-Si and its low deposition rate, the zinc oxide layer of the present embodiment enhance light absorption via light trapping to take advantage of the potentially large current density that can be generated by nc-Si.

In another embodiment, a method for sputtering a textured zinc oxide coating onto a substrate using the sputter reactor set forth above. The method comprises establishing a reaction chamber pressure between 80 and 400 mT. A substrate temperature greater than about 170° C. is established. A gas is flown through the channel of the hollow cathode. A plasma is generated such that material is sputtered off the channel-defining surface to form a zinc-containing gaseous mixture containing target atoms that are transported to the substrate. A reactive oxygen containing gas is introduced into the sputter reactor. The reactive gas reacts with the zinc-containing gaseous mixture to form the textured zinc oxide coating. Characteristically, the texture zinc oxide coating scatters at least 1% of visible light incident thereon.

The following examples illustrate the various embodiments of the present invention. Those skilled in the art will recognize many variations that are within the spirit of the present invention and scope of the claims.

### Example #1

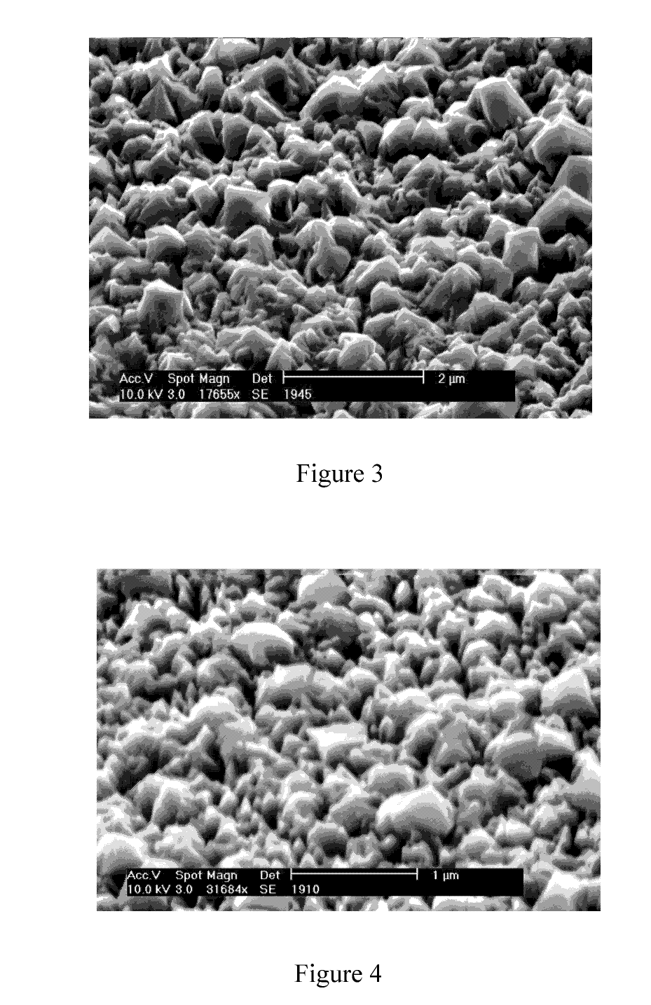

An RE-HCS deposition system containing a linear hollow cathode was fitted with two facing Zn targets 11.4 cm in length and 3.8 cm in breadth. The width of the exit slot so defined was 1.25 cm. An Ar flow of 2 slm was used as the working gas. The reactive gas was water carried by about 100 sccm Ar from a bubbler. The doping element is supplied by sputtering a separate Al bar. Mid-frequency pulsed (bipolar) power was applied on Zn target and Al bar at 100 kHz at a level of 300 W and 100 W, respectively. The chamber pressure was 170 mTorr. The substrate temperature was 230° C. The substrate bias is −80V by RF power. A 1.7 μm ZnO:Al film was grown in 30 minutes using 22 passes across the cathode. The sheet resistance was 4.12 ohm/square corresponding to a film resistivity of 7.0×10⁻⁴ ohm-cm. The film was found to be strongly textured as shown in the scanning electron micrograph of FIG. 3. Further analysis by atomic force microscopy revealed the RMS surface roughness to be 34 nm.

### Example #2

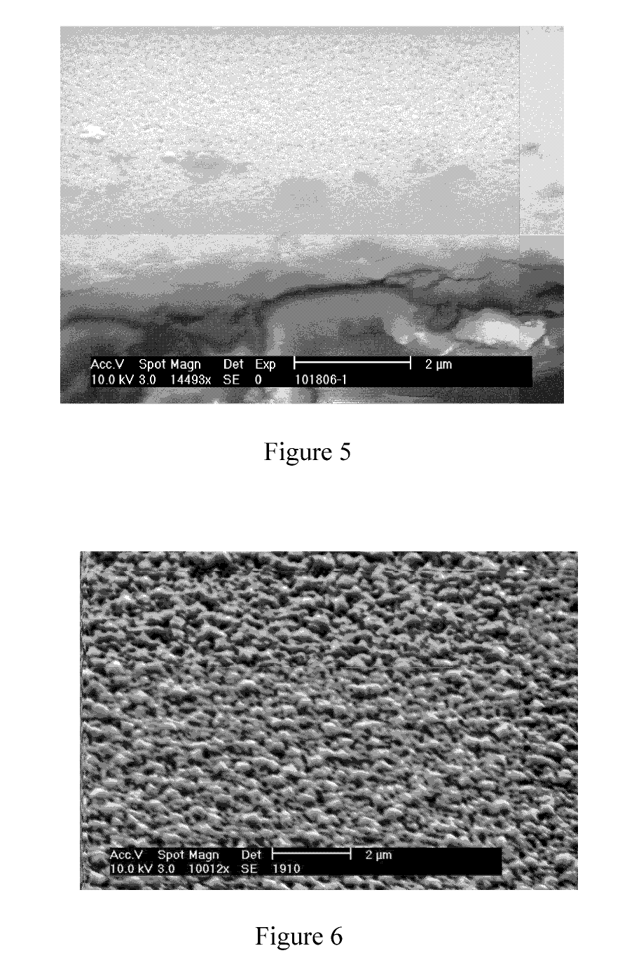

The deposition set-up is similar to example #1. An Ar flow of 2 slm was used as the working gas. The reactive gas was water vapor supplied without an Ar carrying gas. Mid-frequency pulsed (bipolar) power was applied on Zn target and Al bar at 100 kHz at a level of 300 W and 100 W, respectively. The chamber pressure was 170 mTorr. The substrate temperature was 240° C. A 0.99 μm ZnO:Al film was grown in 18 minutes using 13 passes across the cathode. The sheet resistance was 8 ohm/square corresponding to a film resistivity of 7.9×10⁻⁴ ohm-cm. The film was found to be strongly textured as shown in by scanning electron micrograph. Further analysis by atomic force microscopy revealed the RMS surface roughness to be 40 nm. FIG. 4 is an SEM micrograph of textured ZnO:Al film deposited by RE-HCS under the conditions described. For comparative purposes an SEM of zinc oxide from traditional RF sputtering is provided in FIG. 5.

### Example #3

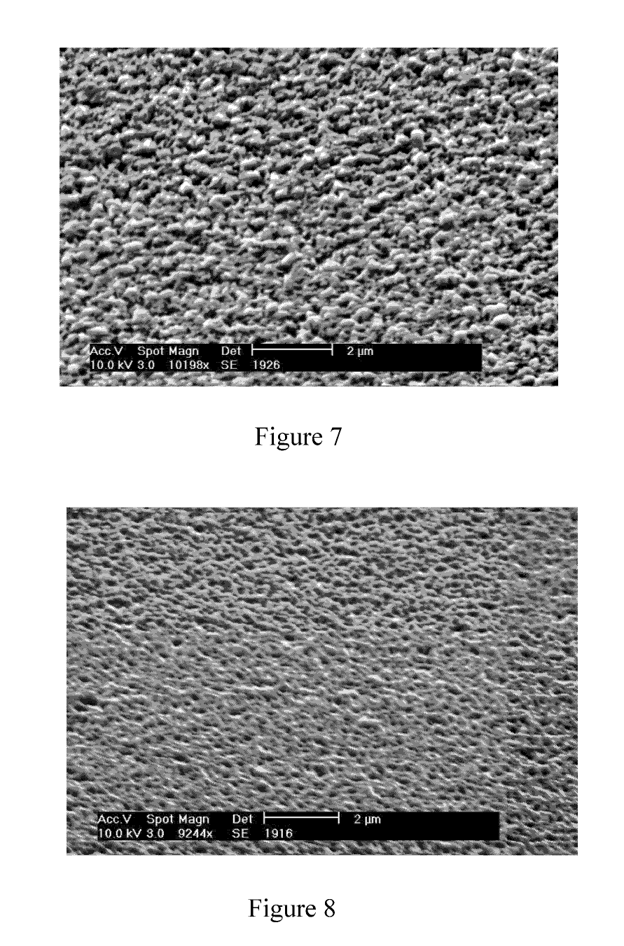

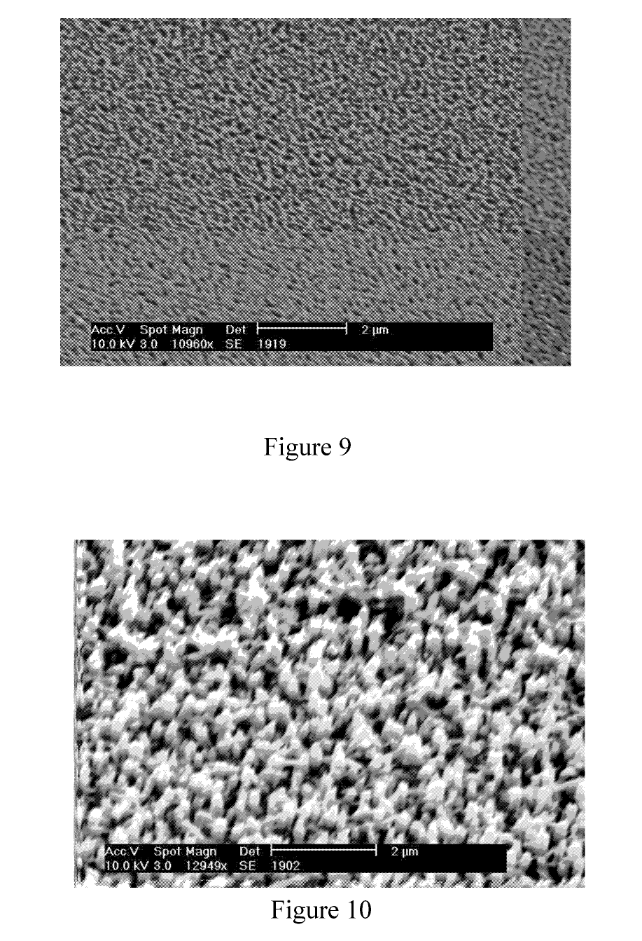

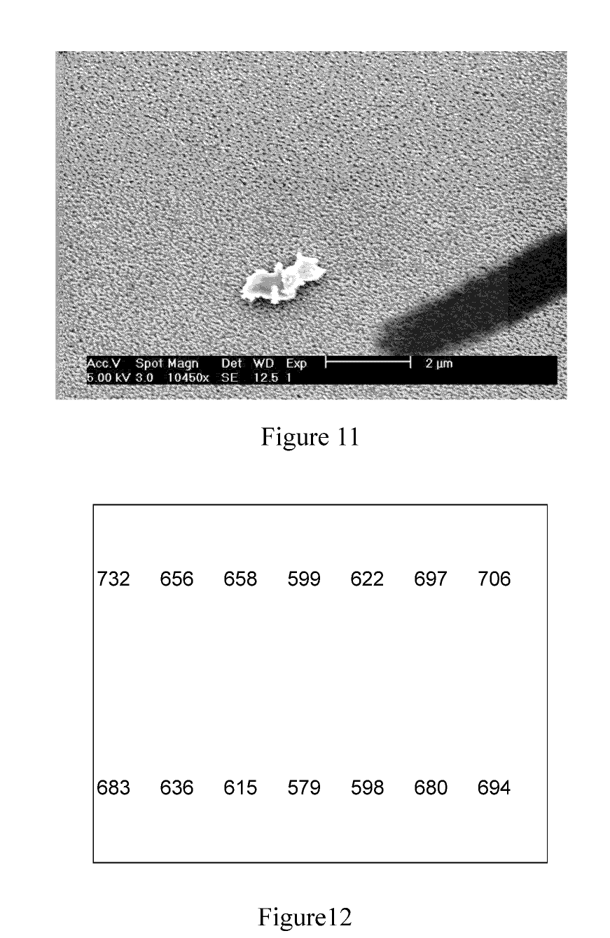

A series of zinc oxide films were formed under various conditions using water or oxygen as the oxygen source. FIG. 6 provides an SEM of a 1 micron thick ZnO film deposited on a substrate at a temperature of 230° C. using water as the oxygen source. The film formed under these conditions had a root mean square (RMS) surface structure of 40.7 nm. FIG. 7 provides an SEM of a 1 micron thick ZnO film deposited on a substrate at a temperature of 230° C. using water as the oxygen source. The bias used for this deposition was −80 V. The film formed under these conditions had a RMS surface structure of 30 nm. FIG. 8 provides an SEM of a 1 micron thick ZnO film deposited on a substrate at a temperature of 230° C. using molecular oxygen as the oxygen source. The bias used for this deposition was −80 V. FIG. 9 provides an SEM of a 1 micron thick ZnO film deposited on a substrate at a temperature of 160° C. using molecular oxygen and water as the oxygen source. FIG. 10 provides an SEM of a 0.58 micron thick ZnO film deposited on a substrate at a temperature of 335° C. using molecular oxygen as the oxygen source. FIG. 11 provides an SEM of a 0.36 micron thick ZnO film deposited on a substrate at a temperature of 120° C. using molecular oxygen as the oxygen source. The RF bias of for this deposition is −60 V.

### Example #4

Aluminum doped zinc oxide films were deposited by reactive environment hollow cathode sputtering as set forth above. In this particular deposition process, atoms sputtered from the interior surfaces of a rectangular (Zn metal) hollow cathode are transported by argon (Ar) gas to a soda lime glass substrate. Oxygen as a reactive gas is supplied externally to the cathode cavity. A cathode assembly with a 50 cm target was installed in-house in a mechanically pumped sputtering chamber with a roller transport assembly. The substrate is heated with an array of quartz heaters and the temperature monitored by thermocouples. Sputtering was carried out at a chamber pressure of about 250 mT with Ar flow rate of 10 slm. A sputtering power of about 2 kW was applied to the cathode assembly in bipolar mode at 100 KHz. The glass substrate temperature was maintained well above 300° C. during deposition of textured films.

Amorphous silicon (a-Si:H) was deposited on ZnO:Al/glass, using the plasma enhanced chemical vapor deposition process. The performance of the cells was studied by current-voltage curves measured at AM1.5 light intensity and spectral, absolute quantum efficiency measurements.

The ZnO:Al films exhibited relatively low resistivities and a dynamic deposition rate (DDR) of 23.2 nm m min⁻¹ for the 50 cm cathode. Initial ZnO:Al films were smooth with a reasonable thickness uniformity. Deposition of strongly textured films with similar thickness uniformity was also achieved. Thickness mapping data of one such ZnO film deposited on 12″×15″ glass is presented in FIG. 12. These textured films had a milky appearance which is indicative of surface texturing. The Al/Zn atomic ratio of these films was found to be in the range of 1-2%.

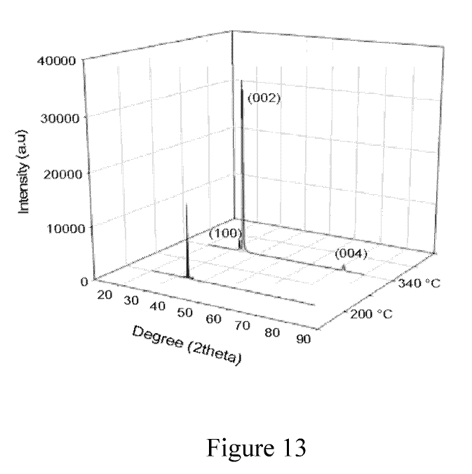

XRD spectra of several ZnO:Al films is shown in FIG. 13. Film deposited at 200° C. (#358) & 340° C. (#365) both have (002) as the prominent peak, which indicates the preferential growth of the film along the (002) direction. The full width half max (FWHM) calculation from XRD spectra indicates an improvement in overall crystallinity of the films at elevated temperature. A similar trend of improved crystalline structure with growth temperature is also observed in RF sputtered non-textured ZnO films.

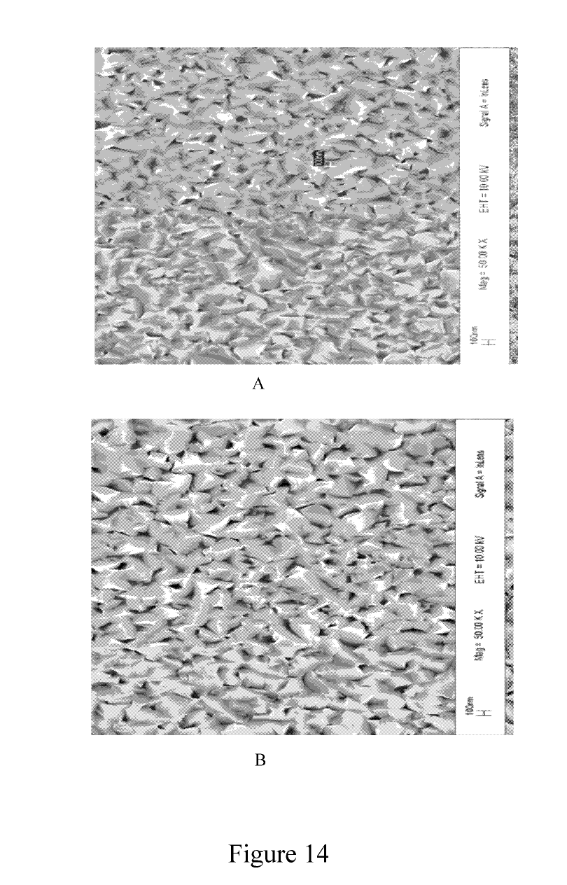

In order to optimize the texturing of the ZnO:Al films, a set of textured films were treated with RF argon plasma for 30 minutes. The morphology of the untreated and treated films is studied by SEM is provided in FIG. 14. The average grain size of the film is about 300 nm. After plasma treatment, small features were removed and the film shows pyramidal grains.

The electrical and optical properties of directly textured ZnO:Al films were recorded by Hall effect measurements and haze meter respectively. The results were compared to the properties of commercial SnO2:F and are shown in Table I.

TABLE 1
Electrical & optical properties of directly textured
ZnO: Al film compared to commercial SnO₂: F.

| Sample | SnO₂: F | ZnO: Al (#386) |
|---|---|---|
| Transmission | 79.5% | 81.4% |
| Haze | 16.4% | 33.0% |
| Film thickness | 564.2 | 1032 |
| (nm) | | |
| Sheet | 13.9-14.8 | 2.77 |
| resistance (Ω/□) | | |
| Mobility | 30.6 | 49.5 |
| (cm²/V-s) | | |
| Carrier | 2.38 × 10²⁰ | 4.42 × 10²⁰ |
| concentration | | |
| (/cm³) | | |
| Resistivity (Ω · cm) | 8.59 × 10⁻⁴ | 2.86 × 10⁻⁴ |

Data presented above shows the superior electrical properties and optical properties of textured ZnO:Al deposited by RE-HCS as compared to SnO2:F. The best mobility of 49.5 cm2/V-s was measured in textured ZnO:Al film (#386) deposited at 340° C., which is the highest value for the sputtered ZnO:Al film, reported in recent literature to our knowledge. The high mobility could be related to the better crystallinity of the film deposited by RE-HCS at high temperature. Moreover, because of the high deposition pressure, our unique RE-HCS technique, unlike magnetron sputtering causes low ion damage to the growing film. In₂O₃:Ti based TCO's with carrier mobility of 80 cm2/V-S have been previously achieved with the RE-HCS.

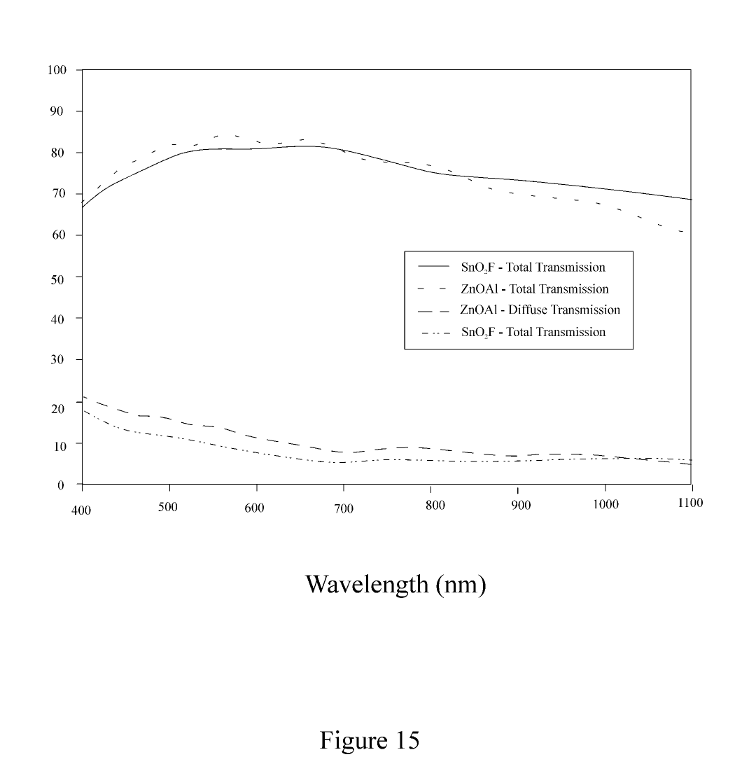

Comparison of the optical transmission (total and diffuse) of RE-HCS ZnO:Al with commercial SnO2:F is presented in FIG. 15. The ZnO:Al film has higher transmission than SnO2:F film even though it is twice as thick. It also shows better light diffusion ability.

As a first application, the doped and textured ZnO films were initially deposited on copper indium gallium diselenide (CIGS) solar cells. The short-circuit photocurrent density and the cell efficiency were increased by 8% and 5%, respectively, through the use of textured ZnO:Al coating. Parameters provides the performance of a CIGS solar cell made with a textured and smooth ZnO is provided in Table 2. The higher efficiency of the cell made from the texture film is significant and indicative of the positive effects of texturing.

TABLE 2
The performance of the CIGS solar cell coated
by textured and smooth ZnO window layer

| | | | | | Efficiency |
|---|---|---|---|---|---|
| Sample | ZnO: Al | Voc | Jsc | FF | (%) |
| H032007-3 | Textured | 565.3 | 33.09 | 67.8 | 12.75 |
| H032007-3A | Smooth | 590.9 | 30.62 | 66.8 | 12.14 |

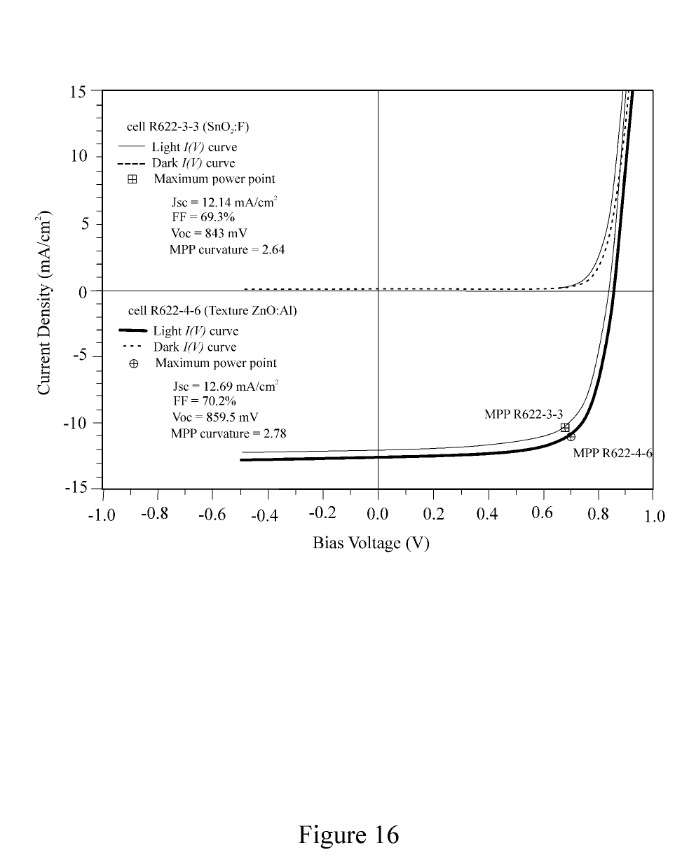

Moderately large size ZnO:Al films were used as the TCO for single junction a-Si:H solar cells with aluminum as the back contact. Performance of a cell deposited on this ZnO:Al/glass was compared to the performance of a cell from the same a-Si growth run deposited on commercial SnO2/glass. Details of the results are presented in FIG. 16 and Table 3.

TABLE 3
Performance of a-Si: H deposited on two different TCO's

| TCO | Voc | Jsc | | |
|---|---|---|---|---|
| (sample#) | (mV) | (mA/cm²) | FF(%) | η (%) |
| RE-HCS | 859.5 | 12.69 | 70.2 | 7.66 |
| ZnO: Al | | | | |
| (R622-4-6) | | | | |
| Commercial | 843.0 | 12.14 | 69.3 | 7.09 |
| SnO₂: F | | | | |
| (R622-3-3) | | | | |

The data indicates improved performance of a-Si:H deposited on textured ZnO. An increase of 8% was noted in the cell efficiency with the use of textured ZnO:Al as compared to SnO2:F TCO. Higher values of Voc, Jsc, and FF in the a-Si:H solar cell have been achieved with ZnO:Al TCO deposited by RE-HCS. The higher Jsc of cells deposited on textured ZnO:Al can be related to higher optical transparency and light trapping.

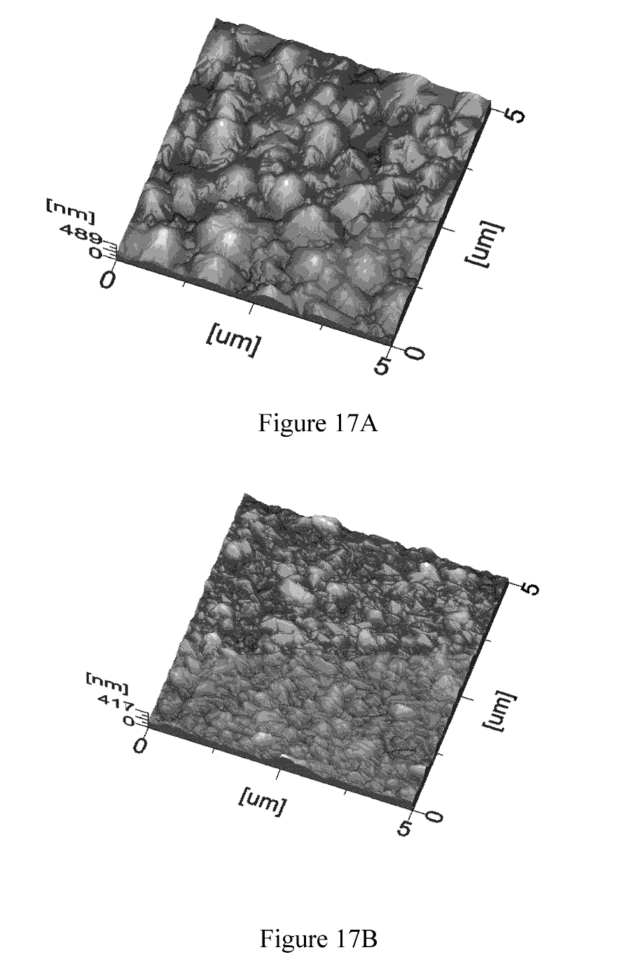

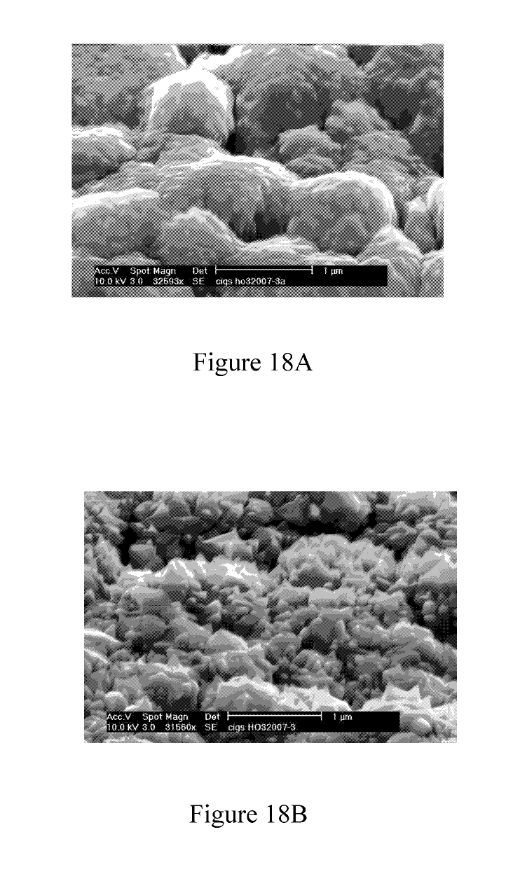

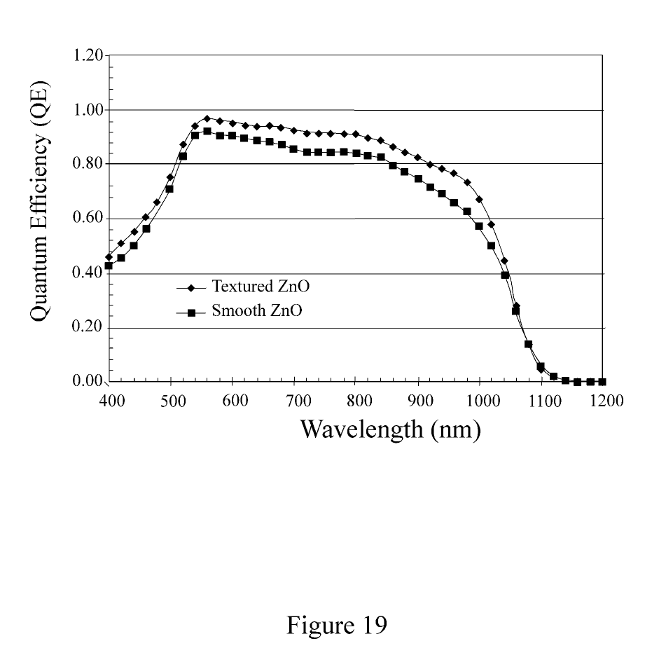

FIG. 17A provides an atomic force micrograph for a textured, doped ZnO film deposited by the RE-HCS process as set forth above. FIG. 17B provides an atomic force micrograph for a commercially available SnO2:F film. FIG. 18A provides an SEM of a CIGS device coated by non-textured ZnO:Al film deposited by RF sputtering while FIG. 18B provides a CIGS device coated by a textured ZnO:Al film deposited by RE-HCS. Table 4 provides topology parameters for textured ZnO and tin oxide films. Table 5 provides optical properties for textured ZnO and commercial SnO₂ coated samples. Finally, FIG. 19 provides a plot of the quantum efficiency versus wavelength for a CIGS device grown on textured ZnO:Al and untextured ZnO:Al.

TABLE 4
The topography parameters of the
textured ZnO film and SnO₂ film.

| | 1961 | | 1963A | | SnO₂ | |
|---|---|---|---|---|---|---|
| Topography | | Stdev | | Stdev | | Stdev |
| parameter | Value | (σ/n) | Value | (σ/n) | Value | (σ/n) |
| RMS (nm) | 81 | 1.45 | 60 | 0.23 | 53 | 0.6 |
| Skewness | 0.39 | 0.04 | 0.25 | 0.016 | 0.56 | 0.03 |
| Kurtosis | 3.35 | 0.09 | 3.07 | 0.06 | 3.61 | 0.145 |
| Density | 124 | 5.2 | 229 | 11.8 | 466 | 3.09 |
| of Summits | | | | | | |
| (peaks/25 μm²) | | | | | | |
| Fastest Decay | 307.54 | 5.94 | 238.33 | 6.35 | 165.72 | 0.6 |
| Length (nm) | | | | | | |
| Mean Summit | 0.03 | 0.002 | 0.045 | 0.001 | 0.033 | 0.001 |
| Curvature | | | | | | |
| (nm⁻¹) | | | | | | |

TABLE 5
the optical properties of the textured
ZnO coated samples and commercial SnO₂

| | | | | T with index match |
|---|---|---|---|---|
| | Thickness | Haze | Transmission T | (index 1.74, a blank |
| Sample | (um) | (%) | (%) | glass cover on film) |
| 1941 | 0.94 | 12.6 | 81.5 | 85.8 |
| 1945 | 1.7 | 48.9 | 78.0 | 83.3 |
| 1956 | 0.92 | 55.5 | 76.5 | 85.5 |
| 1961 | 2.0 | 48.5 | 84.1 | 85.0 |
| 1963A | 2.0 | 31.7 | 80.4 | 84.3 |
| Commercial 1 | 0.6 | 7.6 | 79 | 83.0 |
| (SnO₂) | | | | |
| Commercial 2 | 0.6 | 18.3 | 79.6 | 83.0 |
| (SnO₂) | | | | |

Note:
sample 1956 was deposited at a pressure 300 mTorr, sample 1961 was deposited on borosilicate glass.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method for sputtering a textured zinc oxide coating onto a substrate using a sputter reactor comprising a cathode channel that allows a gas stream to flow therein to a reaction chamber and having a flow exit end, the cathode channel being defined by a channel defining surface, the channel defining surface having at least one zinc containing target, the method comprising:
a) establishing a reaction chamber pressure between 80 and 400 mT;
b) establishing a substrate temperature greater than about 170° C.;
b) flowing a gas through the channel;
c) generating a plasma, wherein material is sputtered off the channel-defining surface to form a zinc-containing gaseous mixture containing target atoms that are transported to the substrate; and
d) introducing a reactive oxygen containing gas into the sputter reactor, the reactive gas reacting with the zinc-containing gaseous mixture to form the textured zinc oxide coating, the textured zinc oxide coating scattering at least 1% of visible light incident thereon.

2. The method of claim 1 wherein the substrate temperature is from about 170° C. to about 400° C.

3. The method of claim 1 wherein the substrate temperature is from about 250° C. to about 350° C.

4. The method of claim 1 wherein textured zinc oxide coating scatters from about 1% to about 75% of visible light incident thereon.

5. The method of claim 1 wherein textured zinc oxide coating scatters from about 20% to about 60% of visible light incident thereon.

6. The method of claim 1 wherein textured zinc oxide coating scatters from about 10% to about 20% of visible light incident thereon.

7. The method of claim 1 wherein textured zinc oxide coating comprises surface features having a size dimension greater than about 0.5 microns.

8. The method of claim 7 wherein at least 10% of the surface features have a size dimension greater than about 0.5 microns.

9. The method of claim 7 wherein at least 20% of the surface features have a size dimension greater than about 0.5 microns.

10. The method of claim 7 wherein at least 30% of the surface features have a size dimension greater than about 0.5 microns.

11. The method of claim 1 further comprising introducing a dopant into the textured zinc oxide coating.

12. The method of claim 1 wherein the textured zinc oxide coating have a resistivity is less than 5×10⁻³ ohm-cm.

13. The method of claim 1 wherein the textured zinc oxide coating have a resistivity is less than 1×10⁻³ ohm-cm.

14. The method of claim 1 wherein the textured zinc oxide coating have a resistivity greater than 1×10⁻⁴ ohm-cm.

15. The method of claim 1 wherein the textured zinc oxide coating has a thickness from 0.5 microns to about 3.0 microns.

16. The method of claim 1 wherein the textured zinc oxide coating has a thickness from about 1.0 microns to about 3.0 microns.

17. The method of claim 1 wherein the reactive oxygen containing gas comprises oxygen, water, or a combination thereof.
